(19) United States
(12) Patent Application Publication
(10) Pub. No.: US 2026/0096337 A1
(43) Pub. Date: Apr. 2, 2026

(54) DISPLAY PANEL AND DISPLAY DEVICE

(71) Applicant: HKC CORPORATION LIMITED, Shenzhen (CN)

(72) Inventors: Jingsong ZHANG, Shenzhen (CN); Qiang CAO, Shenzhen (CN); Jie JIAN, Shenzhen (CN); Ting XIE, Shenzhen (CN); Qi DU, Shenzhen (CN); Lujie WANG, Shenzhen (CN); Pei XU, Shenzhen (CN)

(73) Assignee: HKC CORPORATION LIMITED, Shenzhen (CN)

(21) Appl. No.: 19/331,220

(22) Filed: Sep. 17, 2025

(30) Foreign Application Priority Data
Sep. 30, 2024 (CN) 202411392351.1

(51) Int. Cl. H10K 59/80

(52) U.S. Cl. CPC H10K 59/8792

(57) ABSTRACT

A display panel includes a substrate, a first electrode layer, an anti-peeping layer, a plurality of light-emitting units, a plurality of anti-peeping units and a colored photoresist layer. The first electrode layer is provided at a surface of the substrate; the anti-peeping layer is provided at a surface of the first electrode layer; the plurality of light-emitting units are provided at a surface of the anti-peeping layer at intervals and connected, and an accommodating space is defined between two adjacent light-emitting units; the anti-peeping units are arranged in the accommodating space accordingly; the color photoresist layer is provided at a side of the light-emitting unit facing away from the anti-peeping layer, and its black matrix is arranged corresponding to the anti-peeping unit.

### CROSS-REFERENCE TO RELATED APPLICATIONS

This application claims priority to Chinese Patent Application No. 202411392351.1, filed on Sep. 30, 2024, the entire contents of which are incorporated herein by reference.

### TECHNICAL FIELD

The present application relates to the technical field of display, and in particular to a display panel and a display device.

### BACKGROUND

Organic Light-Emitting Diode (OLED) is a new generation of popular display products with a wide viewing angle of more than 170°, providing users with good visual effects in screen sharing. However, some users hope that the display information with a wide viewing angle will not be seen when browsing personal privacy or business secrets on the display screen to prevent others from peeping. The traditional anti-peeping display mode uses anti-peeping film shutter technology to achieve the anti-peeping effect, which cannot freely control the anti-peeping function. At the same time, the thickness of the anti-peeping film affects the brightness of the light at the normal viewing angle, greatly reducing the user experience.

### SUMMARY

The present application provides a display panel and a display device, aiming to realize the free control of the anti-peeping function without affecting the screen brightness at a normal viewing angle.

In order to achieve the above purpose, the present application provides a display panel, including:
a substrate;
a first electrode layer provided at a surface of the substrate;
an anti-peeping layer provided at a surface of the first electrode layer facing away from the substrate;
a plurality of light-emitting units arranged at intervals on a surface of the anti-peeping layer facing away from the first electrode layer and connected to each other, and an accommodating space being provided between two adjacent light-emitting units;
a plurality of anti-peeping units correspondingly arranged in the accommodating space and located at the surface of the anti-peeping layer facing away from the first electrode layer; and
a color photoresist layer provided at a side of the light-emitting unit facing away from the anti-peeping layer, the color photoresist layer including a color photoresist and a black matrix arranged in an interleaved manner, and the black matrix being arranged corresponding to the anti-peeping unit;
the anti-peeping layer is configured to emit anti-peeping light under a control of the first electrode layer, so that the display panel is in an anti-peeping mode; the anti-peeping unit is configured to become a dark color and undergo expansion deformation in the anti-peeping mode, so that the anti-peeping light emitted by the anti-peeping layer is refracted and emitted through the color photoresist.

In an embodiment, the anti-peeping unit includes:
a stretchable film layer provided at a surface of the anti-peeping layer facing away from the first electrode layer in an accommodating space, and configured to expand and elongate in a direction away from the anti-peeping layer in the anti-peeping mode;
a color changeable film layer provided at both sides of the stretchable film layer in the accommodating space, and configured to change to a dark color in the anti-peeping mode; and
a collimating optical film provided at a side of the stretchable film layer facing away from the anti-peeping layer, and deformed from a straight shape to a bent shape under an action of expansion and elongation of the stretchable film layer, so that the anti-peeping light emitted by the anti-peeping layer is refracted and emitted through the color photoresist.

In an embodiment, under the action of expansion and elongation of the stretchable film layer, the collimating optical film is deformed from a straight shape to a vertex shape, a cone shape or a semicircular shape.

In an embodiment, the anti-peeping layer includes an anti-peeping light source arranged corresponding to the stretchable film layer and the color changeable film layer and is electrically connected to the first electrode layer; and
in the anti-peeping mode, the anti-peeping light source is turned on under an action of voltage of the first electrode layer; the stretchable film layer is configured to expand and elongate in a direction away from the anti-peeping layer under an action of irradiation of the anti-peeping light source, and the color changeable film layer is configured to change to a dark color under the action of irradiation of the anti-peeping light source.

In an embodiment, a material of the stretchable film layer is at least one of graphene oxide liquid crystal network composite material, epoxy azo polymer, and hydrogen bond cross-linked liquid crystal elastomer; and/or
a material of the color changeable film layer is at least one of spiropyran and salicylaldehyde.

In an embodiment, the anti-peeping layer includes an anti-peeping light source arranged corresponding to the stretchable film layer and the color changeable film layer and is electrically connected to the first electrode layer;
the display panel also includes a second electrode layer arranged between the anti-peeping unit and the anti-peeping layer and is electrically connected to the first electrode layer; and
in the anti-peeping mode, the anti-peeping light source is turned on under an action of voltage of the first electrode; the stretchable film layer is configured to expand and elongate in a direction away from the anti-peeping layer under an action of voltage of the second electrode layer, and the color changeable film layer is configured to change to a dark color under the action of voltage of the second electrode layer.

In an embodiment, the material of the stretchable film layer is carbon nanotubes; and/or
the material of the color changeable film layer is at least one of quantum dot metal oxide and nanographene derivative material.

In an embodiment, the display panel also includes a pixel definition layer arranged in the accommodating space and is located on a side of the anti-peeping unit facing away from the anti-peeping layer.

In an embodiment, the light-emitting unit includes a light-emitting bottom electrode layer, a light-emitting layer and a light-emitting top electrode layer arranged in an stacked manner; two adjacent light-emitting units are connected by the light-emitting top electrode layer, and the two adjacent light-emitting units and the light-emitting top electrode layer therebetween jointly form the accommodating space.

In an embodiment, the present application also provides a display device, including: the display panel described above.

According to the technical solution of the present application, the display panel includes a substrate, a first electrode layer, an anti-peeping layer, a plurality of light-emitting units, a plurality of anti-peeping units and a color photoresist layer. The first electrode layer is provided at a surface of the substrate. The anti-peeping layer is provided at a surface of the first electrode layer facing away from the substrate. The plurality of light-emitting units are arranged at intervals on a surface of the anti-peeping layer facing away from the first electrode layer and are connected to each other, and an accommodating space is provided between two adjacent light-emitting units. The plurality of anti-peeping units are arranged correspondingly in the accommodating space and are located on the surface of the anti-peeping layer facing away from the first electrode layer. The color photoresist layer is provided at a side of the light-emitting unit facing away from the anti-peeping layer, the color photoresist layer includes a color photoresists and a black matrix arranged in an interleaved manner, and the black matrix is arranged corresponding to the anti-peeping units. The anti-peeping layer is configured to emit anti-peeping light under the control of the first electrode layer, so that the display panel is in an anti-peeping mode, and the anti-peeping unit is configured to become a dark color and undergo expansion deformation in the anti-peeping mode, so that the anti-peeping light emitted by the anti-peeping light source is refracted and emitted through the color photoresist. The present application utilizes the first electrode layer to freely control the realization of the anti-peeping mode, and in the anti-peeping mode, the anti-peeping unit becomes a dark color and undergo expansion deformation, so that the anti-peeping light emitted by the anti-peeping layer is refracted, and it is emitted through the color photoresist after refraction. The wide-viewing angle light emitted thereby is mixed with the color photoresist, thereby reducing the display effect of the wide viewing angle, that is, the brightness under the wide viewing angle is reduced, and the purpose of anti-peeping is achieved. And, since the anti-peeping unit is arranged in the accommodating space between two adjacent light-emitting units, it will not affect the light output at a normal viewing angle, that is, it will not affect the screen brightness at a normal viewing angle. At the same time, the anti-peeping layer and the anti-peeping unit are integrated in the display panel, which will not affect the overall thickness of the display panel. Therefore, the display panel of the present application achieves the anti-peeping effect without changing the overall thickness of the display panel.

### BRIEF DESCRIPTION OF THE DRAWINGS

In order to illustrate the technical solutions in the embodiments of the present application or in the related art more clearly, the following briefly introduces the accompanying drawings required for the description of the embodiments or the related art. Obviously, the drawings in the following description are only part of embodiments of the present application. For those skilled in the art, other drawings can also be obtained according to the structures shown in these drawings without any creative effort.

FIG. 1 is a schematic structural diagram of a display panel in a non-anti-peeping mode according to an embodiment of the present application.

FIG. 2 is a schematic structural diagram of the display panel of FIG. 1 in an anti-peeping mode.

FIG. 3 is a schematic structural diagram of the display panel of FIG. 1 from another perspective.

FIG. 4 is a schematic structural diagram of a display panel in the non-anti-peeping mode according to an embodiment of the present application.

FIG. 5 is a schematic structural diagram of the display panel of FIG. 4 in the anti-peeping mode.

FIG. 6 is a schematic structural diagram of the display panel of FIG. 1 from another perspective.

The realization of the objective, functional characteristics, and advantages of the present application are further described with reference to the accompanying drawings.

### DETAILED DESCRIPTION OF THE EMBODIMENTS

The technical solutions of the embodiments of the present application will be described in more detail below with reference to the accompanying drawings. It is obvious that the embodiments to be described are only some rather than all of the embodiments of the present application. All other embodiments obtained by those skilled in the art based on the embodiments of the present application without creative efforts shall fall within the scope of the present application.

It should be noted that if there are directional indications, such as up, down, left, right, front, back, etc., involved in the embodiments of the present application, the directional indications are only used to explain a certain posture as shown in the accompanying drawings. If the specific posture changes, the directional indication also changes accordingly.

In addition, if there are descriptions related to “first”, “second”, etc. in the embodiments of the present application, the descriptions of “first”, “second”, etc. are only for the purpose of description, and should not be construed as indicating or implying relative importance or implicitly indicates the number of technical features indicated. Thus, a feature delimited with “first”, “second” may expressly or implicitly include at least one of that feature. Besides, the meaning of “and/or” appearing in the application includes three parallel scenarios. For example, “A and/or B” includes only A, or only B, or both A and B. In addition, the technical solutions between the various embodiments can be combined with each other, but must be based on the realization by those skilled in the art. When the combination of technical solutions is contradictory or cannot be realized, it should be considered that the combination of such technical solutions does not exist or fall within the scope of protection claimed in the present application.

The present application provides a display panel 1000, and the display panel 1000 is an OLED display panel 1000, aiming to realize the free control of the anti-peeping function without affecting the screen brightness at a normal viewing angle.

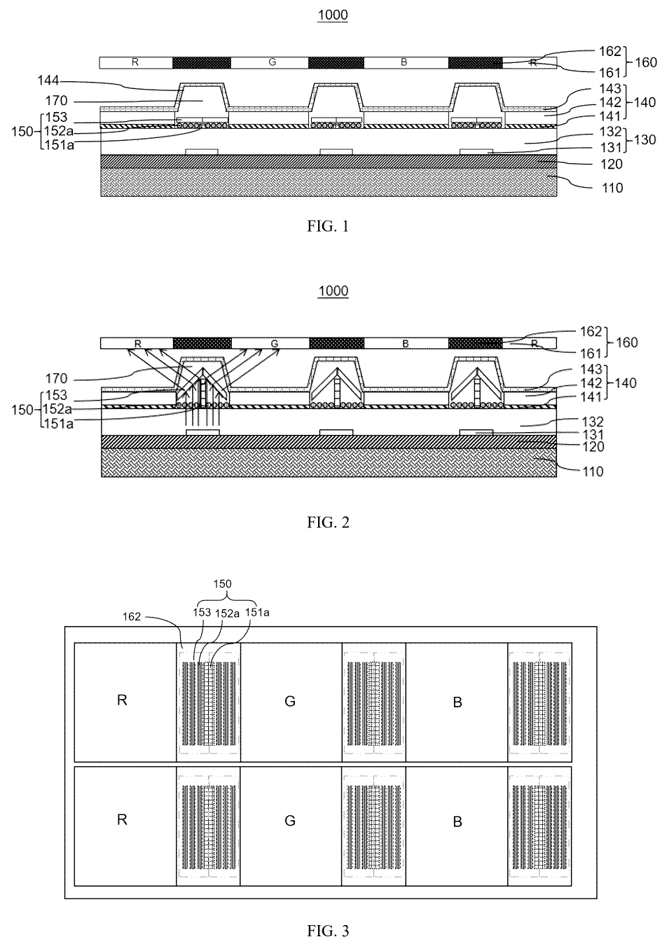

Referring to FIGS. 1 to 6, in an embodiment of the present application, the display panel 1000 includes a substrate 110, a first electrode layer 120, an anti-peeping layer 130, a plurality of light-emitting units 140, a plurality of anti-peeping units 150, and a color photoresist layer 160. The first electrode layer 120 is provided at a surface of the substrate 110. The anti-peeping layer 130 is provided at a surface of the first electrode layer 120 facing away from the substrate 110. The plurality of light-emitting units 140 are arranged at intervals on a surface of the anti-peeping layer 130 facing away from the first electrode layer 120 and are connected to each other, and an accommodating space 144 is provided between two adjacent light-emitting units 140. The plurality of anti-peeping units 150 are correspondingly arranged in the accommodating space 144 and are located at the surface of the anti-peeping layer 130 facing away from the first electrode layer. 120. The color photoresist layer 160 is provided at a side of the light emitting unit 140 facing away from the anti-peeping layer 130. The color photoresist layer 160 includes a color photoresist 161 and a black matrix 162 arranged in an interleaved manner, and the black matrix 162 is arranged corresponding to the anti-peeping unit 150. The anti-peeping layer 130 is configured to emit anti-peeping light under the control of the first electrode layer 120, so that the display panel 1000 is in an anti-peeping mode, and the anti-peeping unit 150 is configured to become a dark color and undergo expansion deformation in the anti-peeping mode, so that the anti-peeping light emitted by the anti-peeping light source 131 is refracted and emitted through the color photoresist 161.

In an embodiment, the substrate 110 may be a transparent substrate, such as a glass substrate, which is used to deposit and manufacture the first electrode layer 120, and the first electrode layer 120 is made of a conductive material and can be applied with a positive voltage or a negative voltage. The color photoresist layer 160 is a red, green, and blue (RGB) photoresist layer; the color photoresist layer 160 is a conventional arrangement, and its specific structural configuration can refer to the prior art. The light-emitting unit 140 corresponds to the color photoresist 161 of the color photoresist layer 160 and is used to emit light at a normal viewing angle. The anti-peeping unit 150 is arranged in the accommodating space 144 between two adjacent light-emitting units 140, and the anti-peeping unit 150 corresponds to the black matrix 162 of the color photoresist layer 160, so that the non-luminous area can be well utilized to achieve the anti-peeping effect, and the anti-peeping effect is relatively high. When the first electrode layer 120 is not applied with voltage, the display panel 1000 is in the non-anti-peeping mode. At this time, the peep layer 130 does not emit peeping light, the peeping function is not turned on, and the light-emitting unit 140 can display normally under normal viewing angle and wide viewing angle. When the first electrode layer 120 is applied with voltage, the peeping layer 130 can emit peeping light under the control of the first electrode layer 120, so that the display panel 1000 is in an anti-peeping mode. In the anti-peeping mode, the peeping unit 150 becomes a dark color and undergo expansion deformation. At this time, the peeping light emitted by the peeping layer 130 is refracted upon irradiating the anti-peeping units 150 and is emitted by the color photoresist 161, and the large viewing angle light emitted thereby is mixed with the color photoresist 161, thereby reducing the display effect of the wide viewing angle and achieving the purpose of peeping.

It should be noted that the specific structure and material of the peeping unit 150 are not limited, as long as it can achieve variable dark color and expansion, elongation and deformation to reduce the display effect of the wide viewing angle.

The technical solution of the present application can freely control the anti-peeping mode by using the first electrode layer 120, and in the anti-peeping mode, the anti-peeping unit 150 becomes a dark color and undergo expansion deformation, so that the anti-peeping light emitted by the anti-peeping layer 130 is refracted, and it is emitted through the color photoresist 161 after refraction. The large viewing angle light emitted thereby is mixed with the color photoresist 161, thereby reducing the display effect of the large viewing angle, that is, the brightness under the large viewing angle is reduced, and the purpose of anti-peeping is achieved. Since the anti-peeping unit 150 is arranged in the accommodating space 144 between two adjacent light-emitting units 140, it will not affect the light output at a normal viewing angle, that is, it will not affect the screen brightness at a normal viewing angle. At the same time, the anti-peeping layer 130 and the anti-peeping unit 150 are integrated in the display panel 1000 and will not affect the overall thickness of the display panel 1000. Therefore, the display panel 1000 of the present application achieves the anti-peeping effect without changing the thickness of the display panel 1000.

Please refer to FIGS. 1 to 6 again, in an embodiment of the present application, the anti-peeping unit 150 includes a stretchable film layer, a color changeable film layer and a collimating optical film 153. The stretchable film layer is provided at the surface of the anti-peeping layer 130 facing away from the first electrode layer 120 in the accommodating space 144, and can expand and elongate in the direction away from the anti-peeping layer 130 in the anti-peeping mode. The color changeable film layer is provided at both sides of the stretchable film layer in the accommodating space 144, and can change to a dark color in the anti-peeping mode. The collimating optical film 153 is provided at the side of the stretchable film layer facing away from the anti-peeping layer 130, and deforms from a straight shape to a bent shape under the action of expansion and eongation of the stretchable film layer, so that the anti-peeping light emitted by the anti-peeping layer 130 is refracted and emitted through the color photoresist 161.

In an embodiment, the stretchable film layer is arranged in an middle part of the surface of the anti-peeping layer 130 facing away from the first electrode layer 120 in the accommodating space 144. In the anti-peeping mode, the stretchable film layer expands and elongates in the direction away from the anti-peeping layer 130. The color changeable film layer is located at both sides of the stretchable film layer and is symmetrically distributed. In the anti-peeping mode, the color changeable film layer changes from a transparent layer to a dark color. The collimating optical film 153 is used for light transmission. The collimating optical film 153 is a straight shape in the non-anti-peeping mode and is provided at the surface of the stretchable film layer and the color changeable film layer facing away from the anti-peeping layer 130, it can transmit light normally. The collimating optical film 153 may be a multi-segment structure or a bendable and deformable structure. In the anti-peeping mode, the collimating optical film 153 is deformed by the support force of the stretchable film layer, and deforms from the original straight shape to a bent shape. The light emitted by the anti-peeping layer 130 passes through the color changeable film layer and then irradiates the deformed collimating optical film 153, cauing refraction, which is emitted by the color photoresist 161, the large-angle light emitted thereby is mixed with the color photoresist 161. Since the color changeable film layer is dark-colored, the display effect of the large-angle view can be effectively reduced.

It should be noted that the specific structural configuration and material of the stretchable film layer are not limited, as long as it can achieve expansion and eongation, the stretchable film layer can be made of photodeformable material or electrodeformable material. The specific structural configuration and material of the color changeable film layer are not limited, as long as it can achieve the transformation between the transparent color and dark color, the color changeable film layer may be made of photochromic material or photochromic material.

In an embodiment of the present application, under the action of expansion and eongation of the stretchable film layer, the collimating optical film 153 is deformed from a straight shape to a vertex shape, a cone shape or a semicircular shape.

In an embodiment, the collimating optical film 153 includes two-segment structure which is connected. In the anti-peeping mode, the collimating optical film 153 is deformed by the support force of the stretchable film layer, and the original straight shape is deformed to a vertex shape. Such the structure is simple and the manufacturing cost is low.

In an embodiment, the collimating optical film 153 includes three-segment structure which is connected. In the anti-peeping mode, the collimating optical film 153 is deformed by the support force of the stretchable film layer, and the original straight shape is deformed into a cone shape. Alternatively, the collimating optical film 153 includes three-segment structure which is connected, and the middle section is semicircular. In the anti-peeping mode, the collimating optical film 153 is deformed by the support force of the stretchable film layer, and the original straight shape is deformed into a semicircular shape.

In an embodiment, the collimating optical film 153 can also include more than three-segment structure which is connected, and the shape of each section is not limited, that is, the shape of the collimating optical film 153 after bending and deformating is not limited, as long as it can achieve the anti-peeping light refracted to a wide viewing angle and mixed with the color photoresist 161 to reduce the display effect of the wide viewing angle.

Please refer to FIGS. 1 to 3, in an embodiment of the present application, the anti-peeping layer 130 includes an anti-peeping light source 131. The anti-peeping light source 131 is arranged corresponding to the stretchable film layer and the color changeable film layer, and is electrically connected to the first electrode layer 120. In the anti-peeping mode, the anti-peeping light source 131 is turned on under the action of voltage of the first electrode layer 120; the stretchable film layer may expand and elongate in a direction away from the anti-peeping layer 130 under the action of irradiation of the anti-peeping light source 131, and the color changeable film layer may change to a dark color under the action of irradiation of the anti-peeping light source 131.

In this embodiment, the stretchable film layer is a photostrictive film layer 151a, and the color changeable film layer is a photochromic film layer 152a. The anti-peeping light source 131 is arranged corresponding to the photostrictive film layer 151a and the photochromic film layer 152a. In the non-anti-peeping mode, the peep light source 131 is in an off state, the peeping function is not turned on, and the light-emitting unit 140 can display normally under a large viewing angle. In the anti-peeping mode, under the action of voltage of the first electrode layer 120, the anti-peeping light source 131 is turned on; the photochromic film layer 152a changes from a transparent color to a dark color under the action of irradiation of the anti-peeping light source 131; the photostrictive film layer 151a gradually expands and elongates in a direction away from the anti-peeping layer 130 under the action of irradiation of the anti-peeping light source 131, and the collimating optical film 153 is deformed by the support force of the photostrictive film layer 151a, and is deformed from the original straight shape to the vertex shape. At the same time, the anti-peeping light emitted by the anti-peeping light source 131 passes through the dark photochromic film layer 152a and irradiates the bent collimating optical film 153, cauing refraction, which is emitted by the color photoresist 161, and the large-angle light emitted thereby is mixed with the color photoresist 161. Since the photochromic film layer 152a is dark-colored, the display effect of the large-angle view can be effectively reduced.

It should be noted that the principle of photochromism is: photochromism refers to a compound A that undergoes a photochemical reaction to obtain a product B when irradiated with light of a certain wavelength, and the colors of A and B (i.e., the absorption of light) are significantly different. At the same time, B can be restored to its original form A under the irradiation of another beam of light or after heating. This photochromic mechanism is determined by the characteristics of the material itself.

In an embodiment, the material of the photochromic film layer 152a is at least one of spiropyran and salicylaldehyde.

The principle of photostrictive deformation is: the photodeformable material is a smart material that deforms under the irradiation of light waves. The material of the photostrictive film layer 151a can be selected from at least one of graphene oxide liquid crystal network composite materials, epoxy azo polymers, and hydrogen bond cross-linked liquid crystal elastomer.

It can be understood that, in this embodiment, the photochromic principle and the photodeformation principle are used to achieve the anti-peeping effect. That is, in the anti-peeping mode, the anti-peeping light source 131 is turned on under the action of voltage of the first electrode layer 120, and the photochromic film layer 152a is irradiated by the anti-peeping light source 131, changing from a transparent color to a dark color. The light passing through the dark photochromic film layer 152a is refracted to a wide viewing angle through the bent and deformed photostrictive film layer 151a, and is emitted by the color photoresist 161, and mixed with the color photoresist 161, which effectively reducing the display effect of the wide viewing angle and achieving the anti-peeping effect. In the non-anti-peeping mode, no voltage is applied to the first electrode layer 120; the anti-peeping light source 131 is turned off; the photochromic film layer 152a returns to its original transparent color, and the photostrictive film layer 151a returns to its original shape.

In an embodiment of the present application, the anti-peeping layer 130 also includes a light board 132, the light board 132 is arranged between the first electrode layer 120 and the light-emitting unit 140. The light board 132 faces the first electrode layer 120 and is provided with a mounting groove on the surface corresponding to the photochromic film layer 152a and the photostrictive film layer 151a. The anti-peeping light source 131 is located in the mounting groove and is electrically connected to the first electrode layer 120. In an embodiment, the light board 132 is made of an optically homogeneous material, which can ensure that the direction of the light of the anti-peeping light source 131 is not affected during the transmission process.

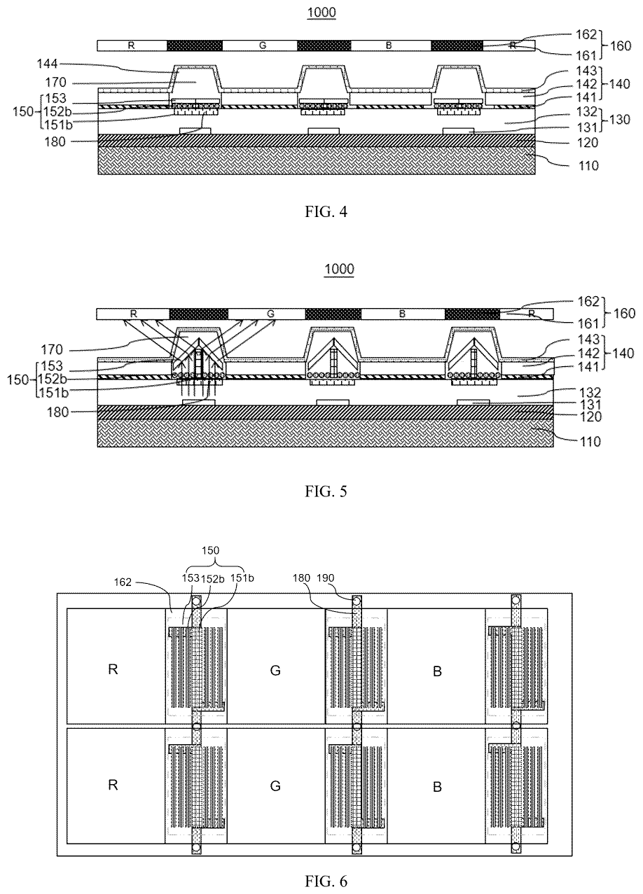

Please refer to FIGS. 4 to 6, in an embodiment of the present application, the anti-peeping layer 130 includes an anti-peeping light source 131, and the anti-peeping light source 131 is arranged corresponding to the stretchable film layer and the color changeable film layer and is electrically connected to the first electrode layer 120. The display panel 1000 also includes a second electrode layer 180, and the second electrode layer 180 is arranged between the anti-peeping unit 150 and the anti-peeping layer 130 and is electrically connected to the first electrode layer 120. In the anti-peeping mode, the anti-peeping light source 131 is turned on under the action of the voltage of the first electrode; the stretchable film layer may expand and elongate in a direction away from the anti-peeping layer 130 under the action of voltage of the second electrode layer 180, and the color changeable film layer may become a dark color under the action of voltage of the second electrode layer 180.

In this embodiment, the stretchable film layer is an electrostrictive film layer 151b, and the color changeable film layer is an electrochromic film layer 152b. The anti-peeping light source 131 is arranged corresponding to the electrostrictive film layer 151b and the electrochromic film layer 152b. The second electrode layer 180 is made of a conductive material, and the second electrode layer 180 is arranged corresponding to the electrostrictive film layer 151b and the electrochromic film layer 152b, and is in contact with the electrostrictive film layer 151b and the electrochromic film layer 152b. The second electrode layer 180 is connected to the first electrode layer 120 through the conductive layer in the connection through hole 190, and belongs to the same signal, it can be turned on simultaneously when the anti-peeping mode is enabled. In the non-anti-peeping mode, no voltage is applied to the first electrode layer 120 and the second electrode layer 180; the anti-peeping light source 131 is in an off state, the anti-peeping function is not turned on, and the light-emitting unit 140 can display normally under a large viewing angle. In the anti-peeping mode, voltage is applied to the first electrode layer 120 and the second electrode layer 180 simultaneously; the anti-peeping light source 131 is turned on under the action of voltage of the first electrode layer 120; the electrochromic film layer 152b changes from a transparent color to a dark color under the action of voltage of the second electrode layer 180; the electrostrictive film layer 151b gradually expands and elongates in the direction away from the anti-peeping layer 130 under the action of the voltage of the second electrode layer 180, and the collimating optical film 153 is deformed by the support force of the electrostrictive film layer 151b, and is deformed from the original straight shape to the vertex shape. At the same time, the anti-peeping light emitted by the anti-peeping light source 131 passes through the dark electrochromic film layer 152b and irradiates the curved collimating optical film 153, causing refraction, which is emitted by the colored photoresist 161, and the wide-viewing angle light emitted thereby is mixed with the colored photoresist 161. Since the electrochromic film layer 152b is dark-colored, the display effect at a wide viewing angle can be effectively reduced.

It should be noted that electrochromism is a phenomenon in which the optical properties (reflectivity, transmittance, absorptivity, etc.) of a material undergo stable and reversible color changes under the action of an external electric field. In appearance, it manifests as a reversible change in color and transparency, which is determined by the material itself.

In an embodiment, the material of the electrochromic film layer 152b is at least one of quantum dot metal oxide and nanographene derivative material.

Electrostriction refers to the phenomenon that a dielectric undergoes elastic deformation in an electric field. This phenomenon is specifically: when a dielectric is placed in an electric field, its molecules are polarized, and along the direction of the electric field, the positive pole of one molecule is connected to the negative pole of another molecule. Due to the mutual attraction between the positive and negative poles, the entire dielectric shrinks in this direction until the elastic force inside it is balanced with the electric attraction, which is determined by the material itself.

In an embodiment, the material of the stretchable film layer is carbon nanotube.

It can be understood that in this embodiment, the electrochromic principle and the electrodeformation principle are used to achieve the anti-peeping effect. That is, in the anti-peeping mode, voltage is applied to the first electrode layer 120 and the second electrode layer 180 simultaneously, the anti-peeping light source 131 is turned on under the action of voltage of the first electrode layer 120, and the electrochromic film layer 152b changes from a transparent color to a dark color under the action of voltage of the second electrode layer 180. The light passing through the dark electrochromic film layer 152b is refracted to a wide viewing angle through the bent and deformed electrostrictive film layer 151b, and is emitted by the color photoresist 161, and mixed with the color photoresist 161, which effectively reducing the display effect of the wide viewing angle, and achieving the anti-peeping effect. In the non-anti-peeping mode, no voltage is applied to the first electrode layer 120 and the second electrode layer 180; the anti-peeping light source 131 is turned off, the electrochromic film layer 152b returns to its original transparent color, and the electrostrictive film layer 151b returns to its original shape.

In an embodiment of the present application, the anti-peeping layer 130 also includes a light board 132, and the light board 132 is arranged between the first electrode layer 120 and the light-emitting unit 140. The light board 132 is provided with a mounting groove on the surface facing the first electrode layer 120 and corresponding to the electrochromic film layer 152b and the electrostrictive film layer 151b, and the anti-peeping light source 131 is located in the mounting groove and electrically connected to the first electrode layer 120. In an embodiment, the light board 132 is made of an optically homogeneous material, which can ensure that the direction of the anti-peeping light source 131 is not affected during the light transmission process.

It should be noted that the photochromic film layer 152a and the electrochromic film layer 152b in the above embodiment may be selected as dark photoresist materials, as long as the purpose of turning on the anti-peeping light source 131 is to reduce the brightness of the large viewing angle display. Alternatively, the photochromic film layer 152a and the electrochromic film layer 152b are selected as transparent materials, and the anti-peeping light source 131 is adjusted to a dark luminous light source, as long as the same anti-peeping effect can be achieved. Dark color means that the gray scale is lower than RGB, and it can be guaranteed to be black after mixing with the color photoresist 161.

Please refer to FIGS. 1, 2, 4 and 5, in some embodiments of the present application, the display panel 1000 also includes a pixel definition layer 170, and the pixel definition layer 170 is provided at a side of the anti-peeping unit 150 facing away from the anti-peeping layer 130 in the accommodating space 144.

In an embodiment, the pixel definition layer 170 is filled in the accommodating space 144, and may be an homogeneous film layer, which can ensure that the light transmission process of the anti-peeping light source 131 does not affect its direction.

Please refer to FIGS. 1, 2, 4 and 5, in some embodiments of the present application, the light-emitting unit 140 includes a light-emitting bottom electrode layer 141, a light-emitting layer 142 and a light-emitting top electrode layer 143 arranged in an stacked manner. Two adjacent light-emitting units 140 are connected by the light-emitting top electrode layer 143, and an accommodating space 144 is provided by two adjacent light-emitting units 140 and the light-emitting top electrode layer 143 therebetween.

The light-emitting unit 140 is configured to emit light. In the non-anti-peeping mode, the light-emitting unit 140 can emit light display at both normal viewing angles and wide viewing angles. In the anti-peeping mode, the light-emitting unit 140 can display normally at normal viewing angles, but cannot display normally at wide viewing angles. The specific structure of the light-emitting unit 140 is a conventional arrangement, and specific reference can be made to the prior art. The accommodating space 144 is provided by two adjacent light-emitting units 140 and the light-emitting top electrode layer 143 therebetween. The shape of the accommodating space 144 can be selected as a trapezoid, a vertex shape, a semicircle or other reasonable shapes, and its internal dimensions are not limited, as long as it allows the stretchable film layer to stretch and the collimating optical film 153 to bend and deform.

In an embodiment, the shape of the accommodating space 144 is consistent with the shape of the collimating optical film 153 after bending and deformation, so that an inner wall of the accommodating space 144 is parallel to a surface of the collimating optical film 153, which is more conducive to preventing the anti-peeping light source 131 from scattering and affecting the anti-peeping effect.

The present application also provides a display device, and the display device includes a display panel 1000. The specific structure of the display panel 1000 refers to the above embodiment. Since the present display device adopts all the technical solutions of all the above embodiments, it at least has all the beneficial effects brought by the technical solutions of the above embodiments, which will not be described one by one here.

The above descriptions are only embodiments of the present application, and are not intended to limit the scope of the present application. Under the inventive concept of the present application, any equivalent structural transformations made by using the contents of the description and drawings of the present application, or direct/indirect applications in other related technical fields are included in the scope of the present application.

What is claimed is:

1. A display panel, comprising:
a substrate;
a first electrode layer provided at a surface of the substrate;
an anti-peeping layer provided at a surface of the first electrode layer facing away from the substrate;
a plurality of light-emitting units arranged at intervals on a surface of the anti-peeping layer facing away from the first electrode layer and connected to each other, and an accommodating space being provided between two adjacent light-emitting units;
a plurality of anti-peeping units correspondingly arranged in the accommodating space and located at the surface of the anti-peeping layer facing away from the first electrode layer; and
a color photoresist layer provided at a side of the light-emitting unit facing away from the anti-peeping layer, the color photoresist layer comprising a color photoresist and a black matrix arranged in an interleaved manner, and the black matrix being arranged corresponding to the anti-peeping unit;
wherein the anti-peeping layer is configured to emit anti-peeping light under a control of the first electrode layer, so that the display panel is in an anti-peeping mode; the anti-peeping unit is configured to become a dark color and undergo expansion deformation in the anti-peeping mode, so that the anti-peeping light emitted by the anti-peeping layer is refracted and emitted through the color photoresist.

2. The display panel according to claim 1, wherein the anti-peeping unit comprises:
a stretchable film layer provided at a surface of the anti-peeping layer facing away from the first electrode layer in an accommodating space, and configured to expand and elongate in a direction away from the anti-peeping layer in the anti-peeping mode;
a color changeable film layer provided at both sides of the stretchable film layer in the accommodating space, and configured to change to a dark color in the anti-peeping mode; and
a collimating optical film provided at a side of the stretchable film layer facing away from the anti-peeping layer, and deformed from a straight shape to a bent shape under an action of expansion and elongation of the stretchable film layer, so that the anti-peeping light emitted by the anti-peeping layer is refracted and emitted through the color photoresist.

3. The display panel according to claim 2, wherein under the action of expansion and elongation of the stretchable film layer, the collimating optical film is deformed from a straight shape to a vertex shape, a cone shape or a semicircular shape.

4. The display panel according to claim 2, wherein:
the anti-peeping layer comprises an anti-peeping light source arranged corresponding to the stretchable film layer and the color changeable film layer and is electrically connected to the first electrode layer; and
in the anti-peeping mode, the anti-peeping light source is turned on under an action of voltage of the first electrode layer; the stretchable film layer is configured to expand and elongate in a direction away from the anti-peeping layer under an action of irradiation of the anti-peeping light source, and the color changeable film layer is configured to change to a dark color under the action of irradiation of the anti-peeping light source.

5. The display panel according to claim 4, wherein a material of the stretchable film layer is at least one of graphene oxide liquid crystal network composite material, epoxy azo polymer, and hydrogen bond cross-linked liquid crystal elastomer; and/or
a material of the color changeable film layer is at least one of spiropyran and salicylaldehyde.

6. The display panel according to claim 2, wherein:
the anti-peeping layer comprises an anti-peeping light source arranged corresponding to the stretchable film layer and the color changeable film layer and is electrically connected to the first electrode layer;
the display panel further comprises a second electrode layer arranged between the anti-peeping unit and the anti-peeping layer and is electrically connected to the first electrode layer; and
in the anti-peeping mode, the anti-peeping light source is turned on under an action of voltage of the first electrode; the stretchable film layer is configured to expand and elongate in a direction away from the anti-peeping layer under an action of voltage of the second electrode layer, and the color changeable film layer is configured to change to a dark color under the action of voltage of the second electrode layer.

7. The display panel according to claim 6, wherein the material of the stretchable film layer is carbon nanotubes; and/or
the material of the color changeable film layer is at least one of quantum dot metal oxide and nanographene derivative material.

8. The display panel according to claim 1, wherein the display panel further comprises a pixel definition layer arranged in the accommodating space and is located on a side of the anti-peeping unit facing away from the anti-peeping layer.

9. The display panel according to claim 1, wherein the light-emitting unit comprises a light-emitting bottom electrode layer, a light-emitting layer and a light-emitting top electrode layer arranged in an stacked manner; two adjacent light-emitting units are connected by the light-emitting top electrode layer, and the two adjacent light-emitting units and the light-emitting top electrode layer therebetween jointly form the accommodating space.

10. A display device, comprising the display panel according to claim 1.
